(19) United States
(12) Patent Application Publication
(10) Pub. No.: US 2026/0085893 A1
(43) Pub. Date: Mar. 26, 2026

(54) COOLING COMPONENT AND METHOD FOR PRODUCING SAME

(71) Applicant: ERWIN QUARDER SYSTEMTECHNIK GMBH, Espelkamp (DE)

(72) Inventors: Alexander HEITBRINK, Stemwede (DE); David LÖTKEMANN, Rahden (DE)

(73) Assignee: ERWIN QUARDER SYSTEMTECHNIK GMBH, Espelkamp (DE)

(21) Appl. No.: 19/404,208

(22) Filed: Dec. 1, 2025

Related U.S. Application Data
(63) Continuation of application No. PCT/EP2024/065526, filed on Jun. 6, 2024.

(30) Foreign Application Priority Data
Jun. 7, 2023 (DE) 102023114998.9

(51) Int. Cl. F28D 1/03; F28D 21/00

(52) U.S. Cl. CPC F28D 1/0316; F28D 2021/0029

(57) ABSTRACT

A cooling component for cooling objects includes a metal profile, forming a heat sink. The profile has multiple parallel medium channels for the flow of cooling medium therethrough, each of which is delimited by a circumferential medium channel wall formed by the profile. The cooling component includes a first connection part made of plastic, which is connected to the profile in a fluid-tight manner, with inlet or outlet opening, via which cooling medium is able to be fed to the cooling component or via which cooling medium is able to be discharged from the cooling component. In the region of the first connection part, the circumferential medium channel wall of at least one of the parallel medium channels has at least one through opening, via which the medium channel is fluidically connected to the inlet or to the outlet opening of the first connection part.

### CROSS-REFERENCE TO RELATED APPLICATIONS

This patent application is a continuation of, and as such claims priority to, International Patent Application No. PCT/EP2024/065526, filed on Jun. 6, 2024, which claims priority to and all advantages of German Patent Application No. DE 10 2023 114 998.9, filed on Jun. 7, 2023; each of the foregoing applications are incorporated herein by reference in their entireties.

### BACKGROUND

Cooling components for discharging heat from objects to be cooled are also referred to as heat exchangers and are used in many technical fields. Such cooling components are of particular importance, for example, during the cooling of battery or accumulator systems, respectively, for electric vehicles, but also of power electronics components, of busbars or of processor chips. The above-mentioned cooling components are thereby generally part of a superordinate cooling device, which ensures that cooling medium, such as, for example, water or the like, is continuously guided through the cooling component. Such cooling components have to often be individualized in a special way depending on the field of application, which leads to high costs.

Cooling bodies of cooling components of this type, which generally rest against the object to be cooled, but which are arranged at least in the immediate vicinity thereof, are thereby often made of individual components made of metal or a metal alloy, such as steel, for example, which are welded or soldered together in a complex manner. The connection part connected to the heat sink for feeding and/or discharging cooling medium often consists of the same metal or of the same metal alloy, respectively, as the heat sink and is likewise welded or soldered thereto in a complex manner.

US 2023/0006281 A1 discloses a heat management system for an electrical component comprising a housing for the electrical component and a heat exchanger plate, which extends over the surface of the side surface of the housing. The plate has a liquid channel between a liquid inlet and a liquid outlet, a feed channel for supplying the plate with liquid and a discharge channel as well as a housing, which defines the housing or the housings, respectively, and receives the heat exchanger plate as well as the discharge channel.

DE 10 2007 003920 A1 relates to a liquid cooler for one or several electrical or electronic components, with a lower cooling plate, on the lower side of which one or several components to be cooled can be arranged and in the upper side of which coolant channels are formed as grooves, which are aligned essentially parallel to the surface plane of the lower cooling plate, with an upper cooling plate, on the upper side of which one or several components to be cooled can be arranged and in the lower side of which coolant channels can be formed a grooves, which are aligned essentially parallel to the surface plane of the upper cooling plate and which are preferably formed in a congruent, thus mirror-inverted manner to the coolant channels in the lower cooling plate, by forming at least one feed through tap bore and at least one discharge through tap bore in the upper or lower cooling plate for the coolant in the direction of the surface normal of the cooling plates, which are fluidically connected to the coolant channels.

### SUMMARY

The present disclosure relates to a cooling component for cooling objects, with at least one, preferably coated, metal profile, which forms a heat sink, as well as a method for producing such a cooling component.

It is the object of the present disclosure to further develop the above-mentioned cooling component as well as to specify a method for producing such a further developed cooling component.

This object is solved by means of a cooling component for cooling objects, with at least one metal profile, which forms a heat sink, wherein the profile has several parallel medium channels for the flow of cooling medium therethrough, each of which is in each case delimited by a circumferential medium channel wall, which is formed by the profile, and with a first connection part made of plastic, which is connected to the profile in a fluid-tight manner with inlet and/or outlet opening, via which cooling medium can be fed to the cooling component and/or via which cooling medium can be discharged from the cooling component, wherein the circumferential medium channel wall of at least one of the parallel medium channels has, in the region of the first connection part, a through opening, via which the medium channel is fluidically connected to the inlet and/or to the outlet opening of the first connection part, wherein the profile is formed with a first large-surface outer side and with a second large-surface outer side spaced apart therefrom, wherein the at least one through opening arranged in the region of the first connection part is arranged on the first or the second large-surface outer side of the profile. Due to the fact that such connection parts are generally not intended for the direct heat transfer from the object to be cooled to the cooling component, it would not actually be required to also produce the connection parts of highly heat-conductive, metal material. Functionally, this is even rather counterproductive.

The object is furthermore solved by means of a method for producing a cooling component, which has at least one metal profile forming a heat sink and which has several parallel medium channels for the flow of cooling medium therethrough, each of which is in each case laterally delimited by a circumferential medium channel wall, which is formed by the profile, and with a first connection part made of plastic, which is connected to the profile in a fluid-tight manner with inlet and/or outlet opening, via which cooling medium can be fed to the cooling component, and/or via which cooling medium can be discharged from the cooling component, wherein the circumferential medium channel wall of at least one of the parallel medium channels has, in the region of the first connection part, a through opening, via which the medium channel is fluidically connected to the inlet and/or to the outlet opening of the first connection part, wherein the profile is formed with a first large-surface outer side and with a second large-surface outer side spaced apart therefrom, wherein the at least one through opening arranged in the region of the first connection part is arranged on the first or the second large-surface outer side of the profile, with the following measures:
a) introducing the through opening into a prefabricated, metal profile in the form of a clearance introduced into the circumferential medium channel wall having the medium channels and the medium channel walls,
b) fluid-tight connection of a prefabricated connection part made of plastic with inlet and/or outlet opening in the region of the through opening.

A cooling component is accordingly specified for cooling objects, which has at least one preferably coated metal profile, which forms a heat sink, preferably an extrusion profile or an extruded profile, respectively, such as, for example, an extrusion molded profile, in particular made of aluminum. This in particular elongated profile has several parallel, in particular elongated medium channels for the flow of cooling medium therethrough, each of which is in each case laterally delimited by a circumferential medium channel wall, the cross section of which is in particular rectangular or approximately circumferential and which is formed by the profile. The profile is connected in a fluid-tight manner to a first connection part made of plastic with an inlet and/or an outlet opening, via which cooling medium can be fed to the cooling component, preferably via the inlet opening, or via which cooling medium can be discharged from the cooling component, respectively, preferably via the outlet opening. In the region of the first connection part, the circumferential medium channel wall of at least one medium channel of the parallel medium channels, preferably the respective circumferential medium channel wall of several or all of said medium channels, thereby has a through opening, which is preferably introduced by means of a manufacturing method, such as separating or shaping, and via which the medium channel is fluidically connected to the inlet or to the outlet opening, respectively, of the first connection part. This is a clearance introduced into the circumferential medium channel wall.

For the purposes of this disclosure, the word “respectively” identifies an example of a feature, which can be used additionally or alternatively. In particular, “respectively” is to be understood like “and/or”.

The above-mentioned method for producing a cooling component, in particular the above-mentioned cooling component, comprises the following measures:
a) introducing the through opening into a prefabricated, metal profile in the form of a clearance introduced into the circumferential medium channel wall having the medium channels and the medium channel walls, in particular by means of a separating and/or shaping method, such as, for example, drilling, punching, pressing and/or bending, preferably by means of laser, drilling device, punching device, pressing device and/or bending device,
b) fluid-tight connecting of a prefabricated, in particular injection molded connection part made of plastic with inlet and/or outlet opening in the region of the through opening, in particular by compressing connection surfaces of the connection part with connection surfaces of the profile, preferably with the use of heat for melting the connection surfaces of the connection part.

The use of at least one metal profile, that is, consisting of optionally coated metal or a metal alloy, together with at least one connection part made of plastic provides for a cost-efficient production of such a cooling component on the one hand because standardized and well-known production processes of metal profiles can be resorted to, in particular extrusion processes.

On the one hand, the use of a connection part made of plastic is further significantly more cost-efficient than the use of a connection part made of metal or metal alloys, respectively, and, on the other hand, the comparatively low heat conductivity of plastic can be functionally advantageous in this context in order to prevent, for example, an unwanted heat transfer to the cooling medium in the region of the connection part.

Lastly, it is possible to produce cooling components, which are adapted to different application situations, for example in size, shape, profile, arrangement, when using otherwise similar profiles by simply introducing different through openings into the profiles.

For the purposes of this disclosure, exemplary enumerations are not to be considered to be exhaustive but can be supplemented in the context of common general knowledge.

The disclosure likewise also makes it possible to configure different cooling components, in that different plastic connection parts are used for otherwise similar profiles, which can optionally each even have identical through openings.

According to a first further example, the parallel medium channels can be closed on the front side on their opposite ends. In particular in that opposite sections of the respective circumferential medium channel wall of the respective medium channel are connected to one another in a fluid-tight manner. This preferably in a non-positive manner and/or by means of a substance-to-substance bond, particularly preferably by compression and/or welding of the opposite sections.

With regard to the through opening or through openings, the circumferential medium channel walls of a group of medium channels, which are arranged next to one another, can form a common, cohesive profile opening, which in particular extends transversely to the medium channels. For example in the case of an essentially cuboid profile with parallel medium channels running in the longitudinal extension, upper wall sections, for example, of the circumferential medium channel walls can in each case lie in a common plane and can thereby jointly form the upper profile wall comprising the first large-surface outer side of the cuboid profile, while lower wall sections of the circumferential medium channel walls lying in a common plane accordingly jointly form the lower profile wall, which comprises the second large-surface outer side of the profile. In this case, the mentioned profile opening and/or through opening can in each case be an opening, which runs transversely to the longitudinal extension of the medium channels, in the upper or lower profile wall, which then accordingly simultaneously comprises or forms, respectively, the individual through openings in the upper respective medium channel walls. The individual through openings of the medium channel walls of this group of medium channels would accordingly not be spaced apart from one another but would merge into one another.

Alternatively, it is also conceivable that the through openings of the circumferential medium channel walls of a group of medium channels, which are in each case arranged next to one another, of the profile are in each case separated from one another by preferably parallel material webs formed by the profile, in particular the circumferential medium channel walls. In the above example of an essentially cuboid profile, said through openings could be, for example, parallel slots in the upper or lower profile wall or in the upper or lower wall sections, respectively, of the wall sections, which lie in the common plane, of the circumferential medium channel walls.

Not only the mentioned wall sections of the medium channel walls can therefore preferably be arranged in a common plane but, generally speaking, the through openings of the circumferential medium channel walls of a group of medium channels, which are in each case arranged next to one another, of the profile can accordingly also be arranged in a common plane, which is in particular unbent.

Moreover, it can further apply for several or all medium channels of the profile that the circumferential medium channel walls of in each case two adjacent medium channels can have a common wall section, which is arranged between them and which preferably extends from one end of the profile to the other end of the profile, and which the two adjacent medium channels adjoin in each case.

It can be provided thereby that the common wall section of the circumferential medium channel wall of the two adjacent medium channels is interrupted in at least one region, in particular in at least one end region of the adjacent medium channels, or has a connection opening, so that cooling medium can flow from the one to the other medium channel there. It can be provided correctly thereby that the common wall section separates the two adjacent medium channels from one another in a fluid-tight manner outside the at least one region, in which the wall section is interrupted or outside the at least one connection opening, so that cooling medium cannot flow from the one to the other medium channel there.

A direct connection of said medium channels would be possible in the above-mentioned manner as the interruption or the connection opening, respectively. For example, only in the event that one of the two adjacent medium channels or the assigned circumferential medium channel wall thereof, respectively, has, in the region of a first end of the profile, a through opening, through which cooling medium can be fed via the connection part, the cooling medium could flow through the medium channel and could then flow directly to the other medium channel in the region of a second end via the connection opening or the interruption, respectively, without such a through opening, which is fluidically connected to one or the connection part, likewise being necessary there, and can then subsequently be further guided in the other medium channel, in particular back to the first end. Based on this concept, namely the use of connection openings between adjacent medium channels, which can obviously also be transferred to a group of more than two medium channels, which are each adjacent in this way, various different variations are conceivable in order to design and selectively control the cooling medium flow in the cooling component. Advantageously, an induvial channel control is possible, in the case of which a flow of the cooling medium can be selectively guided through the individual medium channels.

It can further be provided that a first subgroup of the medium channels running in parallel in each case has a through opening, via which the respective medium channel is fluidically connected to the inlet or the outlet opening, respectively, of the first connection part, and a second subgroup in each case has a through opening, via which the respective medium channel is selectively non-fluidically connected to the inlet or the outlet opening, respectively, of the first connection part, but which is closed to the outside in a fluid-tight manner, in particular by means of the first connection part.

This can take place, for example, by means of a suitable wall of the connection part, which covers the through opening after the fluid-tight connecting of the connection part to the profile, so that no cooling medium can flow through the through opening. The use of a kind of “death chamber” is also conceivable, into which the cooling medium can in fact flow through the through opening, but which is closed to the outside and which in particular does not have a fluidic connection to the inlet or outlet opening of the connection part.

For example, through openings in a profile, which are not to be used as part of a certain application, can be closed in this way with the use of a correspondingly formed connection part, which then ensures this closing. In other words, a connection part, which selectively closes certain through openings, could already be selected during the assembly of a cooling component when using a certain profile, which has medium channels, in the circumferential medium channel walls of which certain through openings have already been introduced or are arranged, respectively.

An exemplary individual channel control makes it possible to guide a cooling medium from an inlet chamber in the connection part into individual or several selected medium channels. From there, the medium can be diverted into further medium channels by means of a connector. The diversion of the cooling medium can likewise take place directly in the connection part, so that the medium flows in defined channels, until it is finally guided into the outlet chamber.

In an exemplary design, the connection part and the connector can have diverting spaces in order to provide for the flow of the cooling medium between the different medium channels. The cooling medium is selectively diverted from one medium channel into another medium channel, preferably an adjacent medium channel, in said diverting spaces. This provides for a flexible and controlled control of the cooling medium through the different medium channels of the cooling component.

Alternatively, connection part and connector can be designed without diverting spaces. Instead, exemplary interruptions can be provided in the walls of the medium channels. As described above, the common wall section of the circumferential medium channel wall of the two adjacent medium channels can in particular be interrupted in at least one region, in particular in at least one end region of the adjacent medium channels or can have a connection opening, so that cooling medium can flow from the one to the other medium channel there. Said or connection openings make it possible for the cooling medium to flow from one medium channel directly into the adjacent medium channel. The connection part and the connector seal the openings of the medium channels to the outside in this case, while the cooling medium can flow through the connection openings between the medium channels.

A combination of both variations is likewise possible, wherein diverting spaces as well as connection openings in the channel walls can be used. This offers the advantage that the cooling performance and flow paths of the cooling medium can be adapted even more flexibly and more exactly to the specific cooling requirements. The individual channel control thus provides for a precise control of the cooling medium according to the expected heat dissipation of the components to be cooled, such as, for example, of a battery.

With regard to the setup of the profile, the latter is routinely formed in one piece. The profile has a first large-surface, in particular flat, bent or corrugated outer side, and a first second large-surface, in particular flat, bent or corrugated outer side spaced apart therefrom and in particular running parallel thereto, as well as preferably two in particular flat, bent or corrugated narrow outer sides, which are spaced apart from one another and which in each case connect the first and the second large-surface outer side to one another.

The at least one through opening arranged in the region of the first connection part can then moreover be arranged on the first or the second large-surface outer side of the profile.

The at least one through opening arranged in the region of the first connection part is arranged in the region of a first end of the profile, in particular at a distance therefrom. Alternatively, they can also be arranged in a central region of the profile.

The first connection part can also have an inlet chamber comprising the inlet opening, into which the through opening of the circumferential medium channel wall of the optionally respective medium channel leads, and via which the medium channel is fluidically connected to the inlet opening. In one design, the inlet chamber comprises a plurality of, preferably at least two chamber parts, which are communicatively connected to one another. Alternatively or additionally, the first connection part can also have an outlet chamber, which is in particular separated from the inlet chamber and which comprises the outlet opening and into which the through opening of the circumferential medium channel wall of the optionally respective medium channel leads, via which the medium channel is fluidically connected to the outlet opening. In one design, the outlet chamber comprises a plurality of, preferably at least two chamber parts, which are communicatively connected to one another Alternatively or additionally, the first connection part comprises a diverting space, by means of which a cooling medium can preferably be diverted from at least one first medium channel into at least one second medium channel.

With regard to the circumferential medium channel wall of the optionally respective medium channel, preferably the respective circumferential medium channel wall of the several or of all medium channels, it can thus have a further through opening in the region of a second connection part made of plastic, which is fluidically connected to the profile, in particular a clearance introduced into the circumferential medium channel wall, via which the medium channel is fluidically connected to an inlet or outlet opening of the further connection part.

The circumferential medium channel wall of the optionally respective medium channel, preferably the respective circumferential medium channel wall of the several of or all medium channels, can also have a further through opening in the region of a connector made of plastic, which is connected to the profile in a fluid-tight manner and which in particular diverts the cooling medium and via which said medium channel is fluidically connected to an interior space of the connector, wherein said interior space, in turn, is fluidically connected to at least one further one of the parallel medium channels via a through opening, which is arranged in the region of the connector, in the circumferential medium channel wall of the further medium channel. Alternatively or additionally, the connector comprises a diverting space, by means of which a cooling medium can preferably be diverted from at least one first medium channel into at least one second medium channel.

The second connection part or the connector as well as the at least one through opening arranged in the region of the second connection part or of the connector, respectively, can thereby be arranged at a distance in the region of a second end of the profile lying opposite the first end, namely at a distance from the second end. Alternatively, it can also be provided that the second connection part is arranged in a central region of the profile together with the first connection part.

It is also conceivable that the first connection part and/or the second connection part and/or the connector, in particular one or several walls thereof, is formed in such a way that it separates at least one medium channel from the inlet chamber or the outlet chamber of the first connection part or of the second connection part, respectively, or from the interior space of the connector, so that no cooling medium can flow between said through opening on the one hand and the inlet chamber or the outlet chamber, respectively, or the interior space, respectively, on the other hand. This can in particular relate to a medium channel, which has a through opening, which is preferably introduced by means of separating and/or shaping, in its circumferential medium channel wall in the region of the first connection part or of the second connection part or of the connector.

With the formation of the respective connection part and/or connector or with the use of differently formed connection parts/connectors, respectively, influence can be selectively exerted in this way on which of the medium channels, which are present in the respective profile and the circumferential medium channel wall of which is provided with a through bore, are in fact used in the respective application and which ones are not. For example, a medium channel, which is not required in a certain application, but in the medium channel wall of the in particular prefabricated profile of which a through opening is present, could be locked or shut down, respectively, by means of a corresponding wall of the connection part and/or of the connector, which locks the through opening, so that no cooling medium flows through it.

Based on this concept, namely the selective formation of the respective connection part or of the connector, respectively, various different variations are conceivable for designing the cooling medium flow in the cooling component and for controlling it selectively.

It can be provided in a similar way that the first connection part and/or the second connection part and/or the connector, in particular one or several walls thereof, is formed in such a way that on the one hand it does in fact separate at least two in particular adjacent medium channels, which each have a through opening, which is preferably introduced by separating and/or shaping, in the circumferential medium channel wall thereof in the region of the first connection part or of the second connection part or of the connector, from the inlet opening or from the outlet opening of the first connection part or of the second connection part, respectively, or from an interior space of the connector, which is in contact with through openings of circumferential medium channel walls of other medium channels, so that in particular no cooling medium can flow between the through openings in the circumferential medium channel walls of the in particular adjacent medium channels on the one hand and the inlet chamber or the outlet chamber, respectively, or said interior space, respectively, on the other hand, but it creates a fluidic connection channel between said medium channels on the other hand.

For example, the connection part/the connector or corresponding walls thereof, respectively, could be formed so that the through openings of circumferential medium channel walls of two medium channels of the profile in each case lead into a connection channel, which is delimited by walls of the connection part/of the connector and optionally of the profile or are arranged there, respectively, so that cooling medium can flow from the through opening in the circumferential medium channel wall of the one medium channel into the connection channel, can then flow in the connection channel to the through opening in the circumferential medium channel wall of the other medium channel and can then ultimately flow through this through opening into the other medium channel.

Only for example in the event that one of the medium channels or the assigned circumferential medium channel wall thereof, respectively, has a through opening in the region of a first end of the profile, through which cooling medium can be fed via the connection part, the cooling medium could then flow through said medium channel after feeding, then flow via the connection channel to the other medium channel in the region of a second end and finally be further guided in the other medium channel, in particular back to the first end. Based on this basic concept, in particular the formation and use of such a connection channel between medium channels, which can obviously also be transferred to a group of more than two medium channels, various different variations are conceivable in order to design and selectively control the cooling medium flow in the cooling component.

Particularly preferably, but not exclusively, this can in particular be provided, for example, for two adjacent medium channels, the circumferential medium channel walls of which each have one and/or the common wall section, which is arranged between them and which in particular extends from one end of the profile to the other end of the profile, as already specified above.

### BRIEF DESCRIPTION OF THE DRAWINGS

FIG. 1 shows an example of a cooling component with profile, connection part on one end of the heat sink and connector on the other end of the heat sink, as well as with an object to be cooled, which rests against the cooling component, in an oblique view from the top.

FIG. 2 shows the cooling component, but without object to be cooled, likewise in oblique view from the top.

FIG. 3 shows the cooling component in an exploded illustration.

FIG. 4 shows the cooling component in a top view.

FIG. 5 shows the cooling component in a longitudinal section.

FIG. 6 shows the cooling component in a cross section in the region of the connection part.

FIG. 7 shows the cooling component in a cross section in the region of the connector.

FIG. 8 shows an alternative design of a cooling component.

FIG. 9 shows an exploded view of the design according to FIG. 8.

FIG. 10 shows a further exploded view of the design according to FIG. 8.

FIG. 11 shows a longitudinal section of the design according to FIG. 8 with a rough sketch.

FIG. 12 shows a further alternative design of a cooling component.

FIG. 13 shows an exploded view of the design according to FIG. 11.

FIG. 14 shows a further exploded view of the design according to FIG. 11.

FIG. 15 shows a sectional view of the design according to FIG. 11.

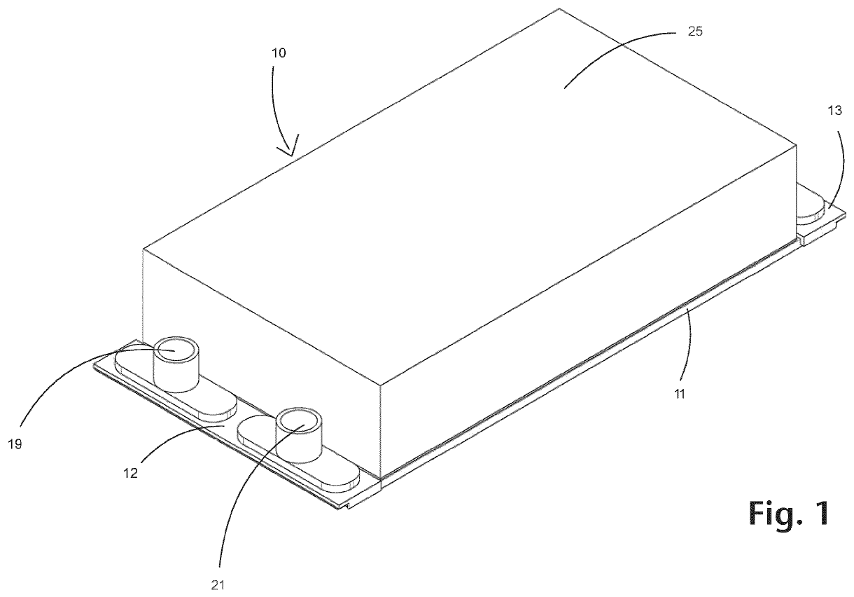

### DETAILED DESCRIPTION

A cooling component 10 is shown in the drawings, as it is used, for example, as part of the cooling of battery or of accumulator systems, respectively, of electric vehicles, in order to cool the respective batteries or the individual cells, respectively. In the present case, such a battery 25 is shown in an exemplary manner.

Such a cooling component 10 is thereby generally part of a superordinate cooling device, which ensures that cooling medium is continuously guided through the cooling component 10, which thereby absorbs waste heat of the object to be cooled and then dissipates said waste heat. The components of the cooling device, which are necessary for this, for example a suitable pump, inlet and outlet lines for the cooling medium, etc., are known in the prior art and are thus not explained in detail.

In the present case, the cooling component 10 can, for example when used, be connected to identical further cooling components of the cooling device, which are not shown here and can then cool several objects to be cooled at the same time, for example several batteries or battery cells, respectively.

The cooling component 10 has a metal profile 11 forming a heat sink, in the present case made of aluminum, which, when used, rests against the object to be cooled or is arranged at least directly adjacent thereto. In the present case, the profile 11 is made in one piece and was produced by means of the aluminum extrusion process, is thus an extruded profile. By nature, the metal profile or the extruded profile, respectively, can also consist of other metal materials.

The profile 11 is formed in an elongated manner, in the present case essentially as flat cuboid.

Based on the main direction of extension of the cooling component 10 or of the profile 11, respectively, a connection part 12 made of plastic is arranged in the region of an end 17 a thereof, via which cooling medium, such as, for example, cooling water or the like, can be fed to the cooling component 10, which cooling medium is then guided within a first group 14 a of elongated medium channels 14 in the main direction of extension of the profile 11 or in the longitudinal direction to the other end 17 b of the profile 11, respectively, is then diverted in a connector 13, which is arranged in a region of this other end 17 b, and flows in the opposite direction through a second group 14 b of elongated medium channels 14 in the opposite direction through the heat sink of the cooling component 10, until it reaches the connection part 12 again and is guided or discharged, respectively, out of the cooling component 10 via the connection part 12.

On its way through the profile 11 or through the medium cannels 14, respectively, the cooling medium absorbs the waste heat of the object to be cooled, here of the battery 25, during operation of the cooling device or of the cooling component 10, respectively, by cooling the object to be cooled and removes said waste heat.

In the present case, the profile 11 has four outer walls 15, namely a first large-surface, upper wall 15 a, a second large-surface lower wall 15 b lying opposite the upper wall in parallel at a distance, as well as two narrow side walls 15 c or 15 d, respectively, which run parallel to one another and which in each case connect the upper wall 15 a and the lower wall 15 b to one another.

The elongated medium channels 14 are arranged in the interior of the profile 11, thus in the interior of the space enclosed by the profile outer walls 15. The medium channels 14 thereby extend parallel to the main direction of extension of the profile 11 or parallel to the narrow side walls 15 c or 15 d, respectively. Based on a cross section through the profile 11, the individual medium channels 14 are arranged next to one another in a row.

Each elongated medium channel 14 is furthermore delimited by a circumferential medium channel wall 16 formed by the profile 11 on preferably all of its longitudinal sides, based on the main direction of extension of the respective medium channel 14. The circumferential medium channel wall 16 thereby describes a hollow cuboid or—in the cross section—a rectangle, respectively, wherein a cuboid is defined as special case of a rectangle in the context of this application.

In the present case, each circumferential medium channel wall 16 thereby in each case comprises concretely two pairs of wall sections each lying opposite one another at a distance.

On the one hand, each medium channel 14 is thereby delimited on two opposite longitudinal sides, which are vertical or run perpendicular, respectively, to the upper and lower large-surface wall 15 a or 15 b, respectively, namely in the transverse direction or perpendicular to the main direction of extension of the profile 11, respectively, by two lateral wall sections 16 a or 16 b, respectively, which in each case run parallel to one another in the main direction of extension of the profile 11 and which are spaced apart from one another. In the case of the two outer medium channels 14, one of said medium channel walls 16 a and 16 b is thereby in each case formed by the respective profile outer wall 15 of the profile 11, in the present case the narrow side wall 15 c or the narrow side wall 15 d, respectively.

On the other hand, each elongated medium channel 14 is in each case delimited on its other two longitudinal sides by an upper wall section 16 a and a lower wall section 16 b. The respective upper wall section 16 a is thereby in each case formed by a subsection of the upper large-surface wall 15 a of the profile 11 and the respective lower wall section 16 b is formed by a subsection of the lower large-surface wall 15 b.

In the present case, each medium channel 14 is furthermore not open on its ends but is closed in a fluid-tight manner on the two opposite profile ends 17 a and 17 b. As part of the manufacture of the cooling component 10, the wall sections 16 a and 16 b of the respective circumferential medium channel wall 16 of the respective medium channel 14 of the profile 11, which in each case initially lie opposite one another there at a distance, were, for this purpose, moved towards one another by means of a corresponding pressing device and were connected to one another in a fluid-tight manner, namely compressed in the present case while creating a weld seam, which was subsequently welded or soldered.

With regard to the connection part 12, the latter has an inlet chamber 18 with upper inlet opening 19, via which cooling medium can be fed to the cooling component 10 and consequently to the medium channels 14 of the first group 14 a of medium channels 14, as well as an outlet chamber 20, which is separated from the inlet chamber 18, with outlet opening 21, via which cooling medium can be discharged from the medium channels 14 of the second group 14 b of medium channels, in particular from the connection part 12 or from the cooling component 10, respectively.

In the present case, each circumferential medium channel wall 16 of each medium channel 14, namely in the present case in each case the upper wall section 16 a thereof, in each case has, for this purpose, in the region of the connection part 12, namely in the present case in the region of the first end 17 a of the profile 11, a through opening 22, via which the respective medium channel 14 is fluidically connected to the inlet opening 19 or to the outlet opening 21, respectively, of the connection part 12. This can in particular be a clearance, which is introduced there, for example, by means of a drilling tool or of a laser.

As can be seen, the individual through openings 22 of the circumferential medium channel walls 16 in each case merge into one another in the transverse direction of the profile 11 in the present case, are thus not spaced apart from one another, so that they form a common, cohesive profile opening 23, which in particular extends transversely to the medium channels 14, in the large-surface upper outer wall 15 a of the profile 11. However, this does not have to be the case, the individual through openings can also be spaced apart from one another.

The connection part 12 is placed onto the upper wall 15 a of the profile 11 so that the inlet chamber 18 and the outlet chamber 20 in each case covers the assigned through openings 22 for the fluidic connection of the respective medium channels 14 or that the through openings 22 lead into the inlet chamber 18, respectively, or the outlet chamber 20, respectively.

Concretely, the through openings 22 of the first group 14 a of medium channels 14 are arranged within the inlet chamber 18 so that the cooling medium can flow directly from the inlet chamber 18 into and/or via the through openings 22 into the medium channels 14 of said first group 14 a and the through openings of the second group 14 b of medium channels of the outlet chamber 20 in such a way that the cooling medium can flow directly from the outlet chamber 20 into and/or via the through openings 22 into the medium channels 14 of this second group 14 b.

With regard to the connector 13, through openings 22, which in the present case form a continuous profile opening 23, are in each case also introduced in the region of said connector, namely in the region of the second profile end 17 b, into the circumferential medium channel walls 16 of the medium channels 14, namely into the respective upper wall sections 16 a. In the case of this example, all of said through openings 22 are covered by this diverting space 24 or the through openings 22 lead into said diverting space, respectively.

Cooling medium, which flows there from the through openings 22 of the first group 14 a of medium channels 14 into the diverting space 24, is diverted in the diverting space 24 to the through openings 22 of the medium channels 14 of the second group 14 b of medium channels 14, enters into them in the opposite direction and then flows—in the second group 14 b of medium channels—through the profile 11 back to the connection part 12.

As already suggested above—in contrast to the profile 11—the connection part 12 as well as the connector 13 do not consist of metal or optionally of a metal alloy but of plastic. In the present case, said components are thereby in each case formed in one piece and are produced as plastic injection molded part, for example of thermoplastic.

For the connection of the connection part 12 and of the connector 13 to the profile 11, connection regions or connection surfaces thereof, respectively, are in each case connected to connection regions or connection surfaces, respectively, of the profile 11 in a fluid-tight manner.

In the present case, the connection surfaces of the metal profile 11 in each case have three-dimensional nanostructures and/or microstructures, which are introduced into the respective surface by means of physical and/or chemical nano-structuring or micro-structuring methods, such as, for example, chemical etching or laser beam structuring.

Each of the connection surfaces of the profile 11, which are structured in the described manner, thereby in each case lies opposite an assigned connection surface of the connection part 12 or of the connector 13, respectively, and is connected thereto, namely for example compressed under thermal joining, as will be described in more detail below.

The concrete production of the cooling component 10 and in particular the above-mentioned connection of the metal cooling component 10 to the connection part 12 consisting of plastic and to the connector 13 consisting of plastic thereby takes place in a special way.

The profile 11, the connection part 12 and the connector 13 are initially prefabricated separately, extruded or injection molded, respectively, in the present case.

The through openings 22 are then introduced into the profile 11 by means of suitable manufacturing methods, such as separating and/or shaping. This can take place, for example, by means of drilling with a suitable, for example mechanical, drilling tool, or by means of a laser. Punching and/or bending and/or pressing of the profile material, preferably by means of punching, bending and/or pressing device, are also possible.

As already described in more detail above, the initially cuboid ends 17 a and 17 b of the profile 11 are additionally compressed by closing the ends of the medium channels 14 of the profile 11, which were previously open on the front side, so that a weld seam is created in each case. This weld seam is then welded or soldered in order to guarantee the fluid-tightness.

The above-mentioned components 11, 12, 13 are generally connected to one another thereafter—it goes without saying that the order of different steps can also be changed. This will be described below in an exemplary manner using the connection of the connection part 12 to the profile 11. The connection of the profile 11 to the connection part 12 takes place analogously.

For the connection of profile 11 and connection part 12, said two components are initially moved and aligned relative to one another. For example, in that the connection part 12 is held in a stationary manner and the profile 11 is moved by means of a suitable conveying member in the direction of the connection part 12. It goes without saying that the process can also run in reverse or that both components can be moved towards one another.

In the course of the above-mentioned relative movement, the profile 11 is then moved relative to the connection part 12 in such a way that the connection surfaces of the profile 11 are placed so as to fit accurately, so that each of the connection surfaces of the profile 11 in each case lies opposite an assigned connection surface of the connection part 12.

Thereafter, during this time and/or before that, the metal profile 11, but at least the connection surfaces 26 of the profile 11, are then heated up or warmed up to a temperature, which corresponds at least to the softening temperature of the plastic of the connection part 12, in particular by means of an induction heater known in the prior art, but other heating techniques are obviously also conceivable.

The heat of the profile 11 is then transferred to the connection part 12 or the connection surfaces thereof, respectively, which then leads to a melting of the connection surfaces.

The respective connection surfaces are then pressed against one another and are thus connected in a fluid-tight manner, for example by means of a or optionally a respective pressing member, such as, for example, a pressing jaw, which is not shown here, which in each case pushes from the outside onto the walls of the connection part 12, which are to be connected, which is to be understood as thermal direct joining.

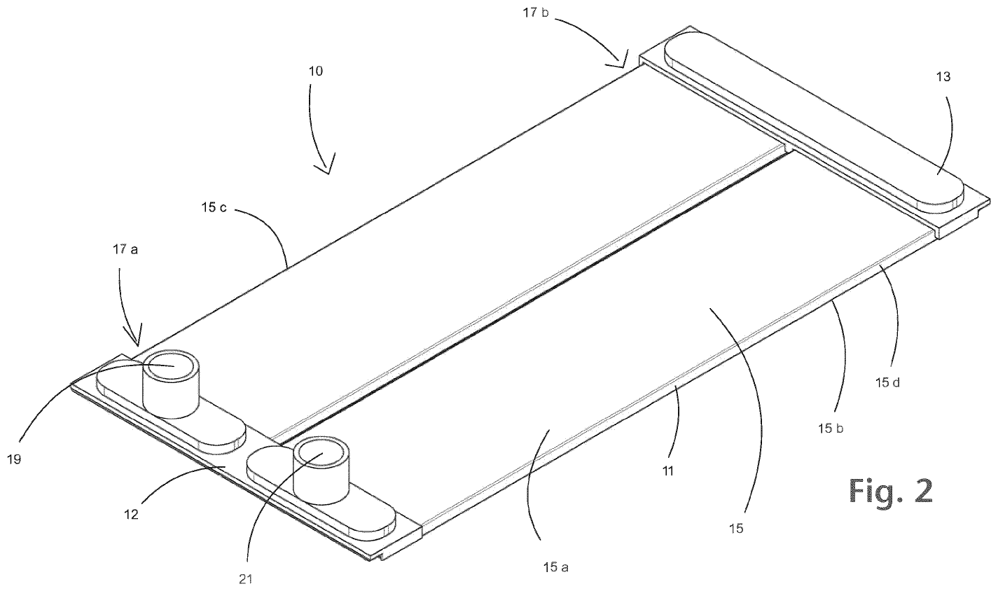

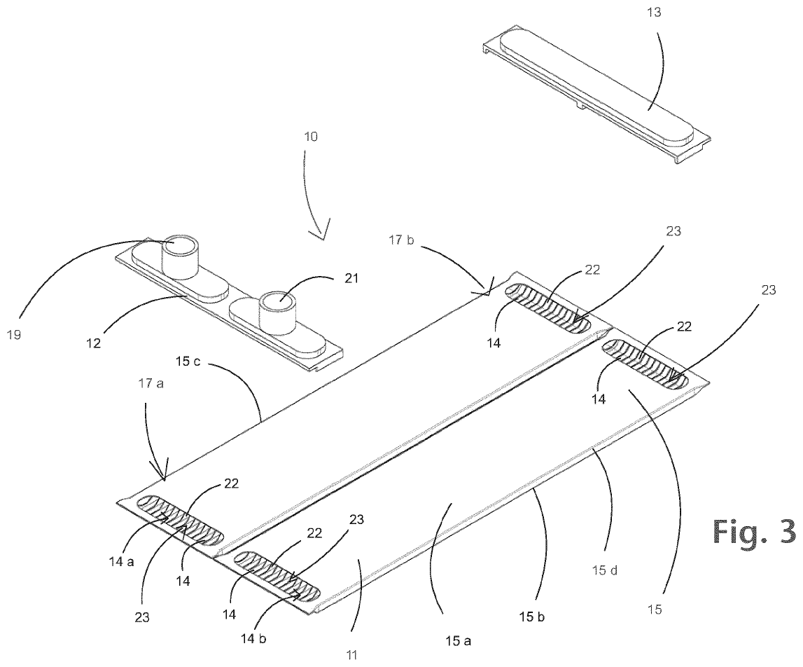

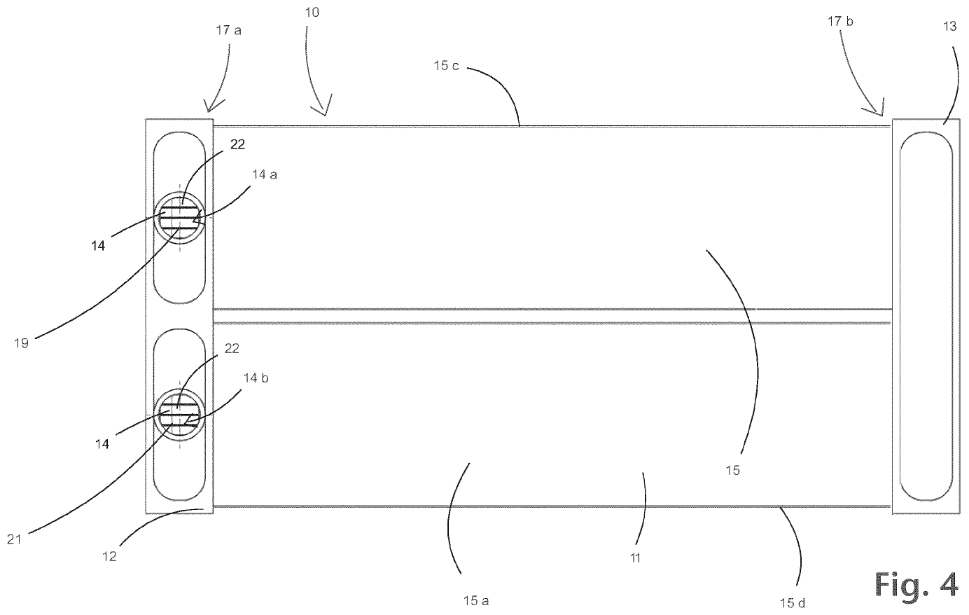

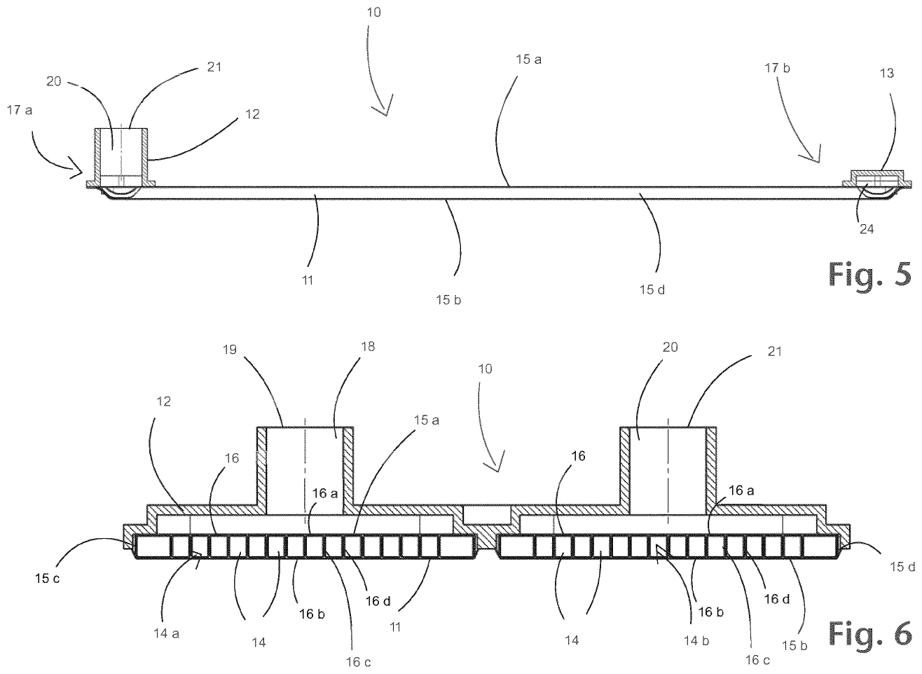

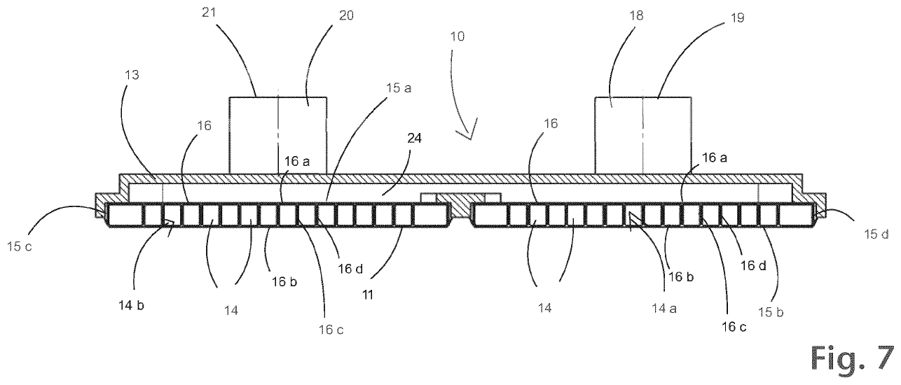

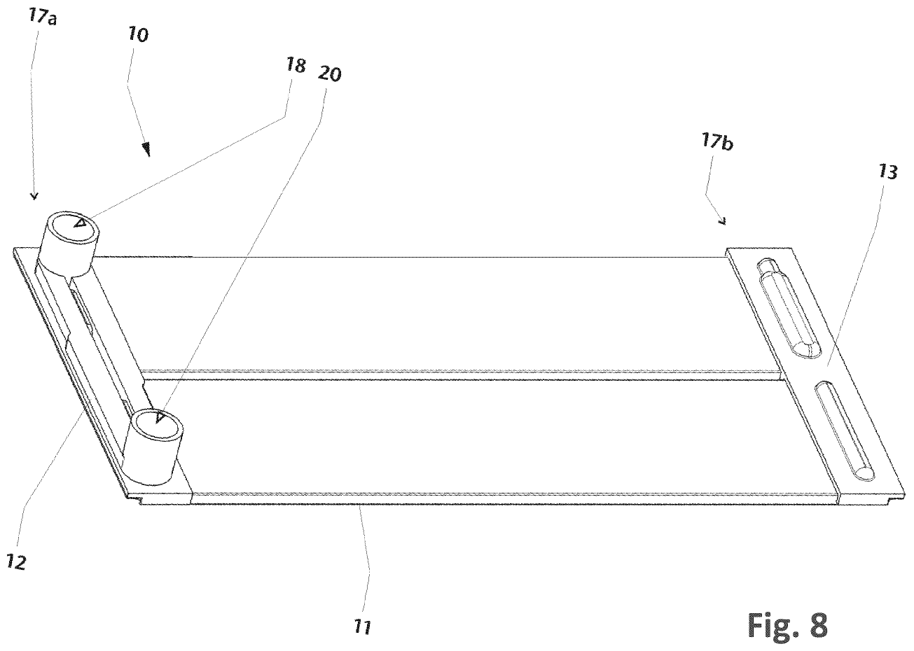

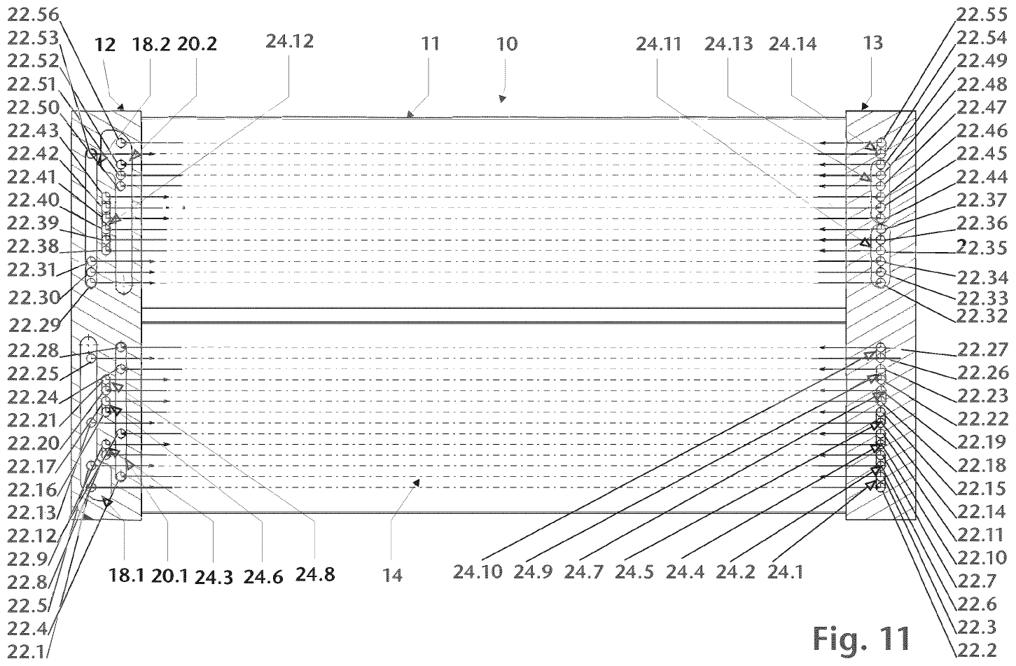

FIG. 8 shows an alternative design of a cooling component 10 with an individual channel control. The cooling component 10 comprises a metal profile 11 forming a heat sink, which is preferably extruded like the above-described profile 11 of FIG. 2. A connection part 12 made of plastic is arranged in the region of a first end 17a. Said connection part comprises an inlet chamber 18, via which the cooling medium can be fed into the cooling component 10. The connection part 12 furthermore comprises an outlet chamber 20, via which the coolant can be discharged from the cooling component 10. The second end 17b of the profile 11 comprises a connection part 13, by means of which a diversion of the coolant in the form of an individual channel control takes place between the medium channels 14, which are outlined in FIG. 11.

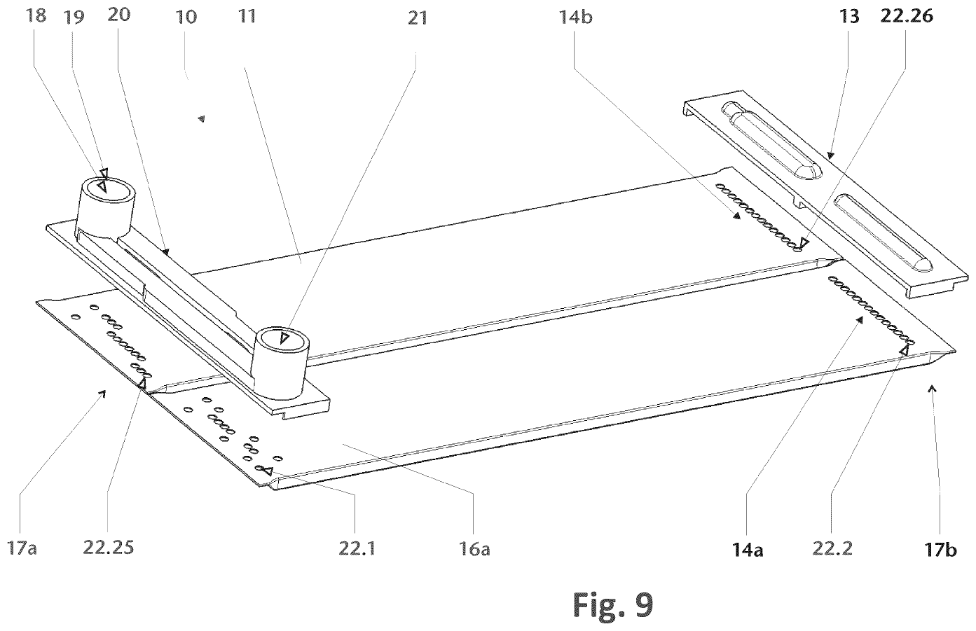

FIG. 9 shows an exploded view of the example according to FIG. 8. The profile 11 of the heat sink 10 comprises a plurality of through openings 22, wherein two through openings 22 for each medium channel 14 are in each case arranged on both ends 17a and 17b of the profile 11. The through openings 22.1 and 22.2 of the medium channels 14 of the first group 14a as well as the through openings 22.25 and 22.26 of the medium channels 14 of the second group 14b are identified in an exemplary manner in FIG. 9. The through openings 22 of the upper medium channel wall 16a are spaced apart from one another and do not merge into one another. Due to the fact that the medium channels 14 in each case have exactly one opening on both ends 17a and 17b, an individual control of the medium channels 14 with cooling medium is possible by means of a correspondingly formed connection part 12 as well as connector 13. An adaptation of the cooling component 10 can thus advantageously be adapted to the expected heat energy dissipation of a battery 25, for example.

The through openings 22 on the first end 17a of the profile 11 are covered completely by the connection part 12. The connection part 12 has the inlet chamber 18 with upper inlet opening 19. The inlet chamber 18 extends over both groups 14a and 14b of the medium channels 14. The connection part 12 furthermore has the outlet chamber 20 with the outlet opening 21. The outlet chamber 20 likewise extends over the two groups 14a and 14b of medium channels 14. As can be seen from FIG. 11, the through openings 22 are arranged on the first end 17a in such a way that they are covered by inlet chamber 18, outlet chamber 20 and diverting spaces.

FIG. 9 furthermore shows that the through openings 22 on the second end 17 of the profile 11 are covered completely by a connector 13.

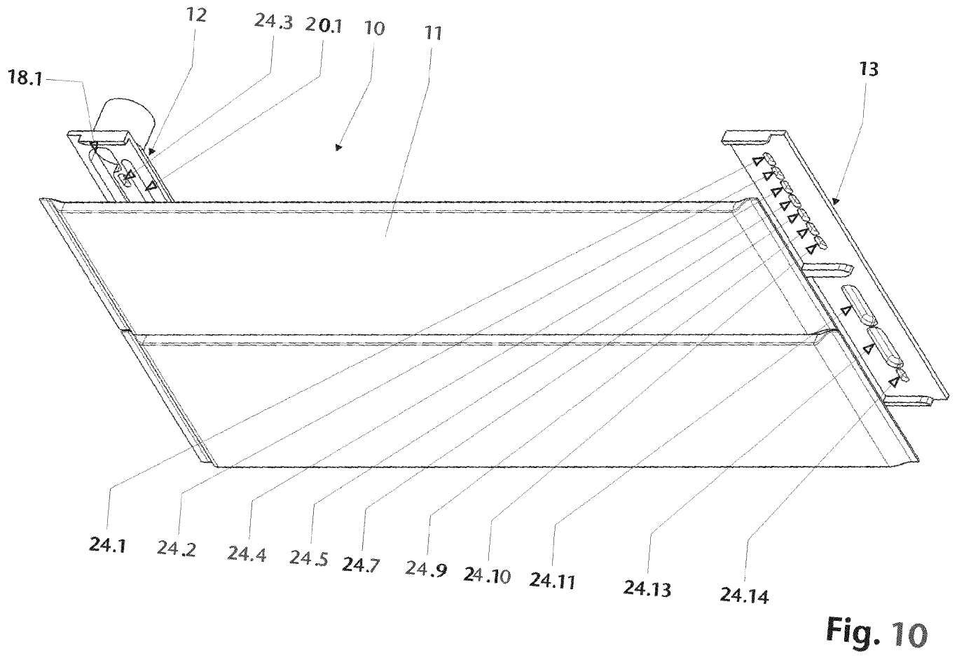

FIG. 10 shows a further exploded view of the cooling component 10 according to FIG. 8. The cooling component 10 can be seen in a perspective view from the bottom. The connection part 12 comprises an inlet chamber 18, a part 18.1 of which is visible here. The outlet chamber 18.2 is covered by the profile 11 and can be seen in FIG. 11. The connection part 12 furthermore comprises an outlet chamber 20, the part 20.1 of which is visible here. The outlet chamber 20.2 is covered by the profile 11 and can be seen in FIG. 11. The connection part 12 furthermore comprises diverting spaces, the diverting space 24.3 of which is visible here. Further diverting spaces of the connection part 12 can be seen in FIG. 11.

FIG. 10 furthermore shows that the connector 13 comprises diverting spaces 24.1, 24.2, 24.4, 24.5, 24.7, 24.9, 24.10, 24.11, 24.13 and 24.14. The individual medium channels 14 outlined in FIG. 11 lead into them in order to divert the cooling medium in further medium channels 14.

FIG. 11 shows the cooling component 10 in a top view, wherein the connection part 12 and the connector 13 are cut longitudinally in a plane parallel to the heat sink. The connection part 12 has the inlet chamber 18, which is divided into two parts 18.1 and 18.2 in the sectional view. The inlet chamber parts 18.1 and 18.2 are communicatively connected to one another. In the sectional view, the outlet chamber 20 is likewise divided into two parts 20.1 and 20.2. Outlet chamber parts 20.1 and 20.2 are communicatively connected to one another.

The inlet chamber 18.1 leads into different medium channels 14 through the through openings 22.1, 22.5, 22.13 and 22.25. For the sake of clarity, the medium channels 14 are not individually provided with reference numerals in FIG. 11 but are outlined by means of arrows, which suggest the flow direction of the cooling medium. The cooling medium, which is fed into a medium channel through the through opening 22.1, is fed through the through opening 22.1 in the diverting space 24.1 and is guided from there via the through openings 22.3 into the adjacent medium channel and is finally fed into the outlet chamber 20.1. Starting at the inlet chamber 18.1, the coolant is furthermore fed through the through opening 22.5 into a medium channel 14 and is further guided through the through opening 22.6 to the diverting space 24.2 of the connector 13 and from there through the through opening 22.7 into a further medium channel 14. A diverting space 24.3, in which the cooling medium is guided from the through opening 22.8 via the through opening 22.9 into a further medium channel 14, is arranged in the connection part 12. The diverting space 24.4 then guides the cooling medium from the through opening 22.10 to the through opening 22.11 into the adjacent medium channel 14, which lastly leads into the outlet chamber 20.1 via the through opening 22.12.

Cooling medium is furthermore guided from the inlet chamber 18.1 via the through opening 22.13 into a medium channel 14. From there, the cooling medium flows through the through opening 22.14 into the diverting space 24.5 and from there through the through opening 22.15 into the adjacent media channel 14. The through opening 22.16 guides the cooling medium into the diverting space 22.6 and from there via the through opening 22.17 into the adjacent medium channel 14. The cooling medium is furthermore guided through the through opening 22.18 into the diverting space 22.7 and from there via the through opening 22.19 into the adjacent medium channel 14. The cooling medium is guided through the through openings 22.20 and 22.21 by means of the diverting space 24.8 into a further medium channel 14, which leads with the through opening 22.22 into the diverting space 24.9. From there, the cooling medium is guided via the through opening 22.23 into a medium channel and finally leads into the outlet chamber 20.1 via the through opening 22.24.

From the inlet chamber 18.1, the cooling medium furthermore flows through the through opening 22.25 into a further medium channel 14, which leads with the through opening 22.26 into the diverting space 24.10. From there, the cooling medium is guided through the through opening 22.27 into the medium channel 14 back through the through opening 22.28 into the outlet chamber 20.1.

The cooling medium is furthermore guided from the inlet chamber 18.1 through the through opening 22.25 into a medium channel 14 and from there through the through opening 22.26 into the diverting space 24.10. From there, the cooling medium is guided through the through opening 22.27 into the adjacent medium channel 14 and then through the through opening 22.28 into the outlet chamber 20.1.

Depending on the expected heat dissipation or cooling demands, respectively, the shown individual channel control can, however, not only control each medium channel 14 individually, but also several medium channels 14 at the same time. Starting at the inlet chamber 18.2, three medium channels 14 are thus fed through the through openings 22.29, 22.30 and 22.31. The medium channels 14 lead with the through openings 22.32, 22.33 and 22.34 into the diverting space 24.11, via which the cooling medium is further guided through the through openings 22.35, 22.36 and 22.37 into three further medium channels 14. A further diverting space 24.12 in the connection part 12 receives the cooling medium through the through openings 22.28, 22.39 and 22.40 and guides it into three adjacent medium channels 14 via the through openings 22.41, 22.42 and 22.43. In the diverting space 24.13, the cooling medium is guided from the through openings 22.44, 22.45 and 22.46 through the through openings 22.47, 22.48 and 22.49 into further medium channels 14. Said medium channels 14 lead via the through openings 22.50, 22.51 and 22.52 into the outlet chamber 20.2. The cooling medium furthermore flows from the inlet chamber 18.2 through the through openings 22.53 and 22.54 into the diverting space 24.14 and from there through the through openings 22.55 and 22.56 into the outlet chamber 20.2.

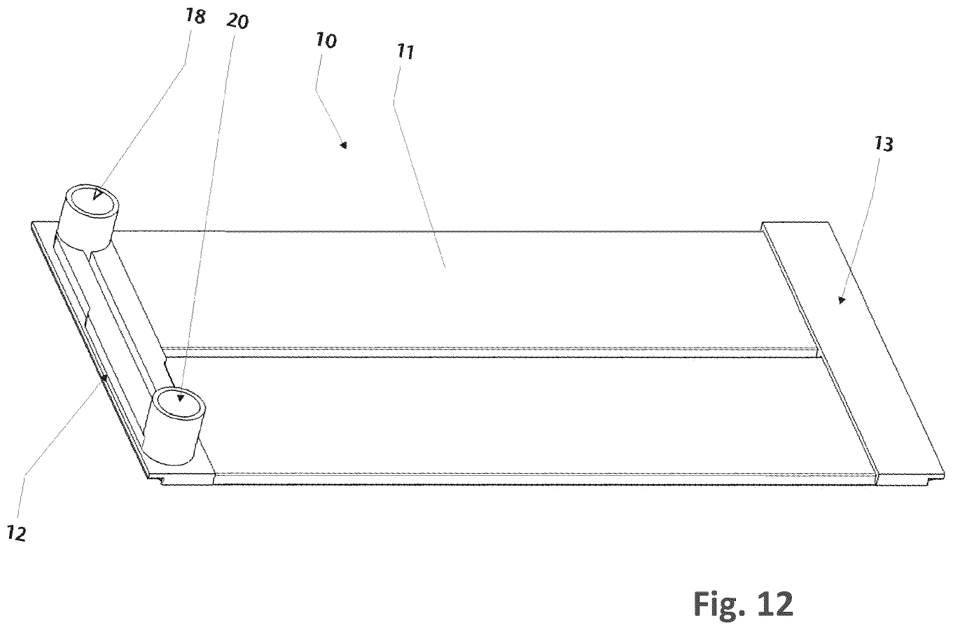

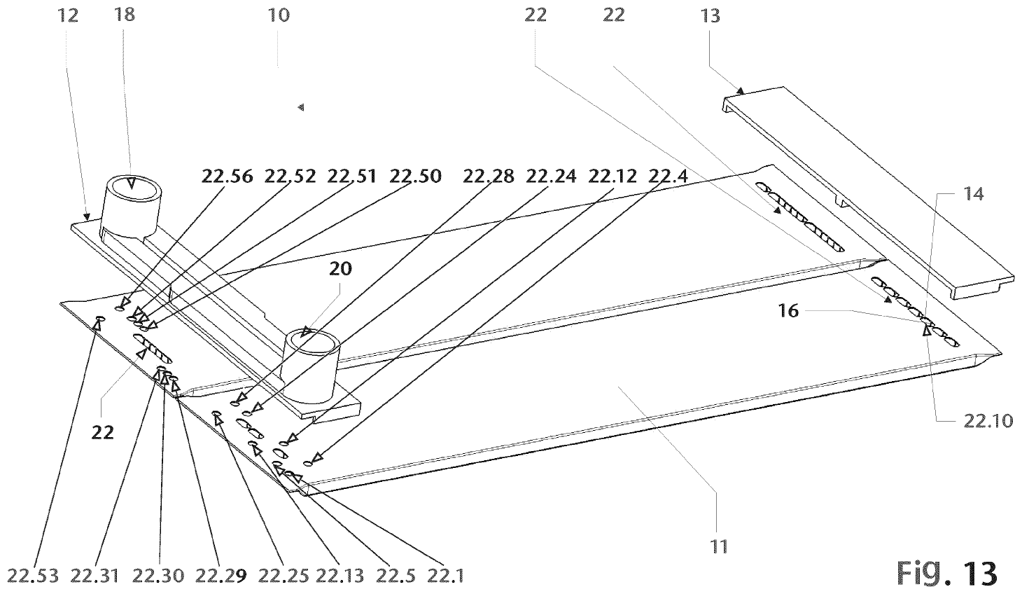

FIG. 12 shows a further alternative design of a cooling component 10 with individual channel control. The profile 11 as well as the connection part 12 with the inlet chamber 18 and the outlet chamber 20 as well as the connector 13 can be seen.

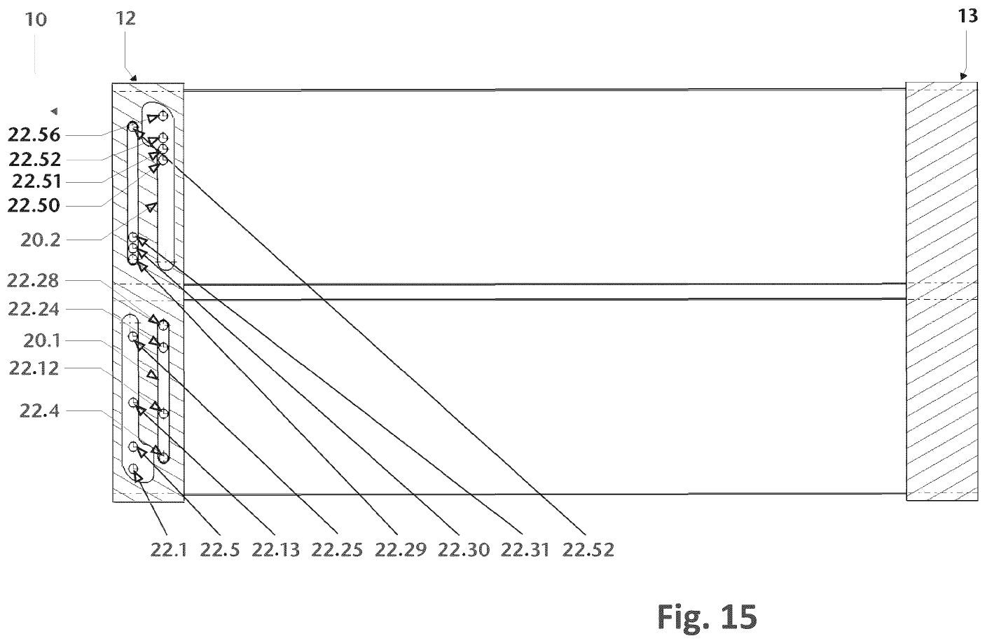

FIG. 13 shows an exploded view of the cooling component 10 according to FIG. 12. The profile 11 comprises a plurality of through openings 22, wherein the through openings 22.1, 22.5, 22.13, 22.25, 22.29, 22.30, 22.31 and 22.53, which are assigned to the inlet chamber 18, which is not visible here, are designed individually and are connected only via the inlet chamber 18, which can be seen in FIG. 15. The through openings 22.4, 22.12, 22.24, 22.28, 22.50, 22.51, 22.52 and 22.56 are also designed individually and are only connected via the outlet chamber 20, which can likewise be seen in FIG. 15. The remaining through openings 22, not all of which are provided with reference numerals here for the sake of clarity, are in particular those through openings 22, which lead into a diverting space 24 in the above-described design. In this example, however, the connection part 12 and the connector 13 do not comprise any diverting spaces. On the contrary, common wall sections of the circumferential medium channel wall 16 of the two adjacent medium channels 14 are interrupted in at least one region, which can be seen in an exemplary manner at the through opening 22.10. Cooling medium can flow in this way from the one to the other medium channel 14. In this design, the connector 13 seals the medium channels 14 towards the top in the region of the through openings 22 on the second end 17b.

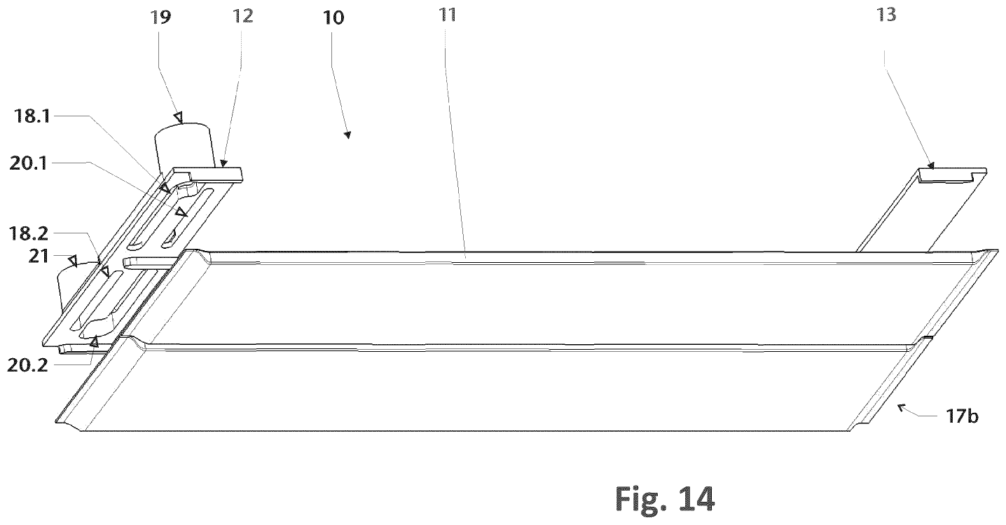

FIG. 14 shows an exploded view of the cooling component 10 from the bottom. The connection part 12 comprises two inlet chambers 18.1 and 18.2, which are communicatively connected to one another and to the inlet opening 19. The connection part 12 furthermore comprises two outlet chambers 20.1 and 20.2, which are communicatively connected to one another and to the outlet opening 21. The connection part 12 does not comprise any diverting spaces. On the contrary, said connection part is designed in a flat manner on the side facing the profile 11 in the region of the through openings 22, which can be seen in FIG. 13 and the common wall sections of the circumferential medium channel wall 16 of which are interrupted in at least one region. The connection part 12 can thus seal exactly said through openings 22 towards the top.

The connector 13, which does not comprise any chambers or diverting spaces, can furthermore be gathered from FIG. 14. On the contrary, all through openings 22, which can be seen in FIG. 13, are sealed on the end 17b towards the top by means of the connector 13. The diverting spaces are not required in this example because common wall sections of the circumferential medium channel wall 16 are interrupted in at least one region, whereby the cooling medium can flow between the medium channels 14, which have the common medium channel wall 16.

FIG. 15 shows the cooling component 10 according to FIG. 12 in a top view, wherein the connection part 12 and the connector 13 are longitudinally cut in a plane parallel to the heat sink. The connection part 12 has the inlet chamber 18, which is divided into two parts 18.1 and 18.2 in the sectional view. The inlet chamber parts 18.1 and 18.2 are communicatively connected to one another. The inlet chamber 18.1, 18.2 leads through the through openings 22.1, 22.5, 22.13, 22.25, 22.29, 22.30, 22.31 and 22.53 into different medium channels 14, which are not illustrated here.

In the sectional view, the outlet chamber 20 is likewise divided into two parts 20.1 and 20.2. Outlet chamber parts 20.1 and 20.2 are communicatively connected to one another. Individual media channels 14 lead via the through openings 22.4, 22.12, 22.24, 22.28, 22.50, 22.51, 22.52 and 22.56 into the outlet chamber 20.1, 20.2.

Neither connection part 12 nor connector 13 comprise a diverting space because the cooling medium can flow between the medium channels 14 by means of the wall interruptions.

The medium channels 14 can advantageously be controlled with cooling medium by means of the individual channel control in the way it is required by an expected distribution of the heat dissipation of a heat source.

List of Reference Numerals

| | |
|---|---|
| 10 | cooling component |
| 11 | profile |
| 12 | connection part |
| 13 | connector |
| 14 | medium channel |
| 14 a | first group of medium channels |
| 14 b | second group of medium channels |
| 15 | outer walls |
| 15 a | first large-surface wall |
| 15 b | second large-surface wall |
| 15 c | narrow side wall |
| 15 d | narrow side wall |
| 16 | circumferential medium channel wall |
| 16 a | upper wall section |
| 16 b | lower wall section |
| 16 c | lateral wall section |
| 16 d | lateral wall section |
| 17 a | profile end |
| 17 b | profile end |
| 18 | inlet chamber |
| 18.1 | inlet chamber |
| 18.2 | inlet chamber |
| 19 | inlet opening |
| 20 | outlet chamber |
| 20.1 | outlet chamber |
| 20.2 | outlet chamber |
| 21 | outlet opening |
| 22 | through opening |
| 22.1. bis 22.56 | through opening |
| 23 | profile opening |
| 24 | diverting space |
| 24.1 bis 24.14 | diverting space |
| 25 | battery |

What is claimed is:

1. A cooling component for cooling objects, comprising:
at least one metal profile, which forms a heat sink, wherein the profile has multiple parallel, elongated medium channels for a flow of cooling medium therethrough, each of which is in each case delimited by a circumferential medium channel wall, which is formed by the profile;
a first connection part made of plastic, which is connected to the profile in a fluid-tight manner, with inlet or outlet opening, via which the cooling medium is able to be fed to the cooling component or via which the cooling medium is able to be discharged from the cooling component, respectively;
wherein in a region of the first connection part, the circumferential medium channel wall of at least one of the parallel medium channels has at least one through opening in the form of a clearance introduced into the circumferential medium channel wall, via which the medium channel is fluidically connected to the inlet or to the outlet opening of the first connection part;
wherein the at least one through opening is a clearance introduced into the circumferential medium channel wall;
wherein the profile is formed with a first large-surface outer side and with a second large-surface outer side spaced apart therefrom; and
wherein the at least one through opening arranged in the region of the first connection part is arranged on the first or the second large-surface outer side of the profile.

2. The cooling component according to claim 1, wherein the parallel medium channels are closed on a front side on their opposite ends, in that opposite sections of the respective circumferential medium channel wall of the respective medium channel are connected to one another in a fluid-tight manner.

3. The cooling component according to claim 1, wherein the at least one through opening includes multiple through openings, and the through openings of the circumferential medium channel walls of a group of medium channels arranged next to one another form a common, cohesive profile opening, which extends transversely to the medium channels.

4. The cooling component according to claim 1, wherein the at least one through opening includes multiple through openings, and the through openings of the circumferential medium channel walls of a group of medium channels, which are in each case arranged next to one another, of the profile are in each case separated from one another by parallel material webs formed by the profile.

5. The cooling component according to claim 1, wherein the at least one through opening includes multiple through openings, and the through openings of the circumferential medium channel walls of a group of medium channels, which are in each case arranged next to one another, of the profile are arranged in a common, unbent plane.

6. The cooling component according to claim 1, wherein the circumferential medium channel walls of two adjacent medium channels have a common wall section, which is arranged between the medium channels and which extends from one end of the profile to the other end of the profile, and which the two adjacent medium channels adjoin in each case.

7. The cooling component according to claim 6, wherein the common wall section of the circumferential medium channel wall of the two adjacent medium channels is interrupted in at least one region, or has a connection opening, so that cooling medium is able to flow from the one to the other medium channel there.

8. The cooling component according to claim 7, wherein the common wall section separates the two medium channels from one another in a fluid-tight manner outside the at least one region, in which the wall section is interrupted or outside the connection opening.

9. The cooling component according to claim 1, wherein the at least one through opening includes multiple through openings, and the circumferential medium channel walls of a first subgroup of the medium channels running in parallel in each case have one of the through openings, via which the respective medium channel is fluidically connected to the inlet or the outlet opening, respectively, of the first connection part, and that the circumferential medium channel walls of a second subgroup of medium channels in each case have one of the through openings, via which the respective medium channel is non-fluidically connected to the inlet or the outlet opening, respectively, of the first connection part, and which is closed to an outside environment in a fluid-tight manner, in particular by means of the first connection part.

10. The cooling component according to claim 1, wherein the profile is formed in one piece.

11. The cooling component according to claim 1, wherein the profile is formed with the first large-surface outer side, with the second large-surface outer side spaced apart therefrom, and with two narrow outer sides, which are spaced apart from one another and which in each case connect the first and the second large-surface outer side to one another.

12. The cooling component according to claim 1, wherein the first connection part and the at least one through opening arranged in the region of the first connection part are arranged in the region of a first end of the profile, at a distance therefrom or in a central region of the profile.

13. The cooling component according to claim 1, wherein the first connection part has an inlet chamber comprising the inlet opening, into which the at least one through opening of the circumferential medium channel wall of the medium channel leads, and via which the medium channel is fluidically connected to the inlet opening, or that the first connection part has an outlet chamber, which is separated from the inlet chamber and which comprises the outlet opening and into which the at least one through opening of the circumferential medium channel wall of the medium channel leads, via which the medium channel is fluidically connected to the outlet opening.

14. The cooling component according to claim 1, wherein the circumferential medium channel wall of the medium channel has a further through opening in the region of a second connection part made of plastic, which is fluidically connected to the profile, via which the medium channel is fluidically connected to an inlet or outlet opening of the second connection part.

15. The cooling component according to claim 14, wherein the second connection part as well as the further through opening arranged in the region of the second connection part are arranged at a distance in the region of a second end of the profile lying opposite a first end, at a distance from the second end, or that the second connection part is arranged in a central region of the profile together with the first connection part.

16. The cooling component according to claim 1, wherein the circumferential medium channel wall of the medium channel has a further through opening in a region of a connector made of plastic, which is connected to the profile in a fluid-tight manner, and via which said medium channel is fluidically connected to an interior space of the connector, wherein said interior space, in turn, is fluidically connected to at least one further one of the parallel medium channels via a further through opening, which is arranged in the region of the connector, in the circumferential medium channel wall of the further medium channel.

17. The cooling component according to claim 1, wherein the first connection part is formed in such a way that it separates at least one medium channel, which has at least one of the at least one through opening in its circumferential medium channel wall in the region of the first connection part, from an inlet chamber or an outlet chamber of the first connection part, so that no cooling medium is able to flow between the at least one of the through opening on the one hand and the inlet chamber or the outlet chamber, respectively, on the other hand.

18. The cooling component according to claim 1, wherein the at least one through opening includes multiple through openings, and the first connection part is formed in such a way that, by forming a connection channel between them, it separates at least two adjacent medium channels, which each have at least one of the through openings, in the circumferential medium channel wall thereof in the region of the first connection part, from the inlet opening or from the outlet opening of the first connection part, so that no cooling medium is able to flow between the through openings in the circumferential medium channel walls of the adjacent medium channels on the one hand and an inlet chamber or an outlet chamber, respectively, on the other hand.

19. A method for producing the cooling component according to claim 1, which has the at least one metal profile forming the heat sink and which has the multiple parallel, elongated medium channels for the flow of cooling medium therethrough, each of which is in each case laterally delimited by the circumferential medium channel wall, which is formed by the profile, and which has the first connection part made of plastic, which is connected to the profile in a fluid-tight manner with the inlet or outlet opening, via which the cooling medium is able to be fed to the cooling component, or via which the cooling medium is able to be discharged from the cooling component, respectively, wherein the circumferential medium channel wall of at least one of the parallel medium channels has, in the region of the first connection part, the at least one through opening, via which the medium channel is fluidically connected to the inlet or to the outlet opening, respectively, of the first connection part, wherein the profile is formed with the first large-surface outer side and with the second large-surface outer side spaced apart therefrom, wherein the at least one through opening arranged in the region of the first connection part is arranged on the first or the second large-surface outer side of the profile with the following measures:
(a) introducing the at least one through opening into a prefabricated, metal profile in the form of a clearance introduced into the circumferential medium channel wall having the medium channels and the medium channel walls, by means of separating or shaping; and
(b) fluid-tight connecting of the prefabricated first connection part made of plastic with the inlet or outlet opening in the region of the at least one through opening, by compressing connection surfaces of the first connection part with connection surfaces of the profile.

20. The method according to claim 19, wherein three-dimensional nanostructures or microstructures are in each case introduced into the connection surfaces of the profile prior to the compressing.

21. The method according to claim 19, wherein the connection surfaces of the profile are brought to a temperature, which corresponds at least to a softening temperature of the plastic of the connection part.

22. The method according to claim 19, wherein the medium channels of the profile are closed on a front side on their opposite ends, by compressing each of two profile ends having the respective ends of the medium channels, so that a weld seam is created in each case.

23. The method according to claim 22, wherein each of the two weld seams is closed in a fluid-tight manner.
